(19) United States
(12) Patent Application Publication
(10) Pub. No.: US 2026/0123541 A1
(43) Pub. Date: Apr. 30, 2026

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: HYEONJEONG HWANG, Suwon-si (KR); JUNGHOON KANG, Suwon-si (KR)

(73) Assignee: SAMSUNG ELECTRONICS CO., LTD., Suwon-si (KR)

(21) Appl. No.: 19/199,962

(22) Filed: May 6, 2025

(30) Foreign Application Priority Data
Oct. 30, 2024 (KR) 10-2024-0150725

(51) Int. Cl. H01L 25/18; G02B 6/42; H01L 23/00; H01L 23/538; H10B 80/00; H10D 80/30

(52) U.S. Cl. CPC H10W 90/00; G02B 6/4239; H10W 70/611; H10W 90/401; H10B 80/00; H10D 80/30; H10W 72/354; H10W 90/722; H10W 90/724; H10W 90/734; H10W 90/792; H10W 90/794

(57) ABSTRACT

There is provided a semiconductor package including a lower structure, a processor chip, a memory chip, and an optical chip on the lower structure, and a leveling structure and an optical structure on the optical chip. The lower structure may include an integrated circuit structure connecting the processor chip to the optical chip and a bridge structure spaced apart from the integrated circuit structure and provided to connect the memory chip to the processor chip. A level of a top surface of the leveling structure may be equal to a level of a top surface of the memory chip, and the leveling structure and the optical structure may be spaced apart from each other.

### CROSS-REFERENCE TO RELATED APPLICATIONS

This U.S. non-provisional patent application is based on and claims priority under 35 U.S.C. § 119 to Korean Patent Application No. 10-2024-0150725, filed on Oct. 30, 2024, in the Korean Intellectual Property Office, the entire contents of which are hereby incorporated by reference.

### BACKGROUND

The disclosure relates to a semiconductor package and a method of fabricating the same, and in particular, to a semiconductor package including an integrated circuit and a method of fabricating the same.

A semiconductor package is configured to facilitate the use of an integrated circuit chip as a component in an electronic product. In general, the semiconductor package includes a printed circuit board (PCB) and a semiconductor chip, which is mounted on the PCB and is electrically connected to the PCB by bonding wires or bumps. As the electronics industry advances, various studies are being conducted to develop a highly reliable, highly integrated, and compact semiconductor package.

In light of recent advancements in the electronics industry, the demand for high-performance, high-speed, and compact electronic components has been steadily increasing. As a result, there is a development of packaging technologies that allow for the mounting of multiple semiconductor chips within a single package.

Recently, a demand for portable electronic devices has been rapidly increasing in the market, and thus, it is necessary to reduce sizes and weights of electronic components constituting the portable electronic devices. For this, it is necessary to develop packaging technologies that reduces a size and a weight of each component and of integrating a plurality of individual components in a single package. In particular, to process high frequency signals, it is necessary to reduce a size of a semiconductor package and improve electrical characteristics of the semiconductor package.

### SUMMARY

One or more aspects of the disclosure provide a method of using a connection structure to reduce a process difficulty and a process cost in a process of fabricating a semiconductor package.

One or more aspects of the disclosure provide a semiconductor package, which is configured to reduce a length of an electrical signal path and to have improved electric characteristics, and a method of fabricating the same.

According to an aspect of the disclosure, there is provided a semiconductor package, including: a lower structure; a processor chip, a memory chip, and an optical chip on the lower structure; and a leveling structure and an optical structure on the optical chip, wherein the lower structure includes: an integrated circuit structure configured to connect the processor chip to the optical chip, and a bridge structure spaced apart from the integrated circuit structure, the bridge structure configured to connect the memory chip to the processor chip, wherein a level of a top surface of the leveling structure is equal to a level of a top surface of the memory chip, and wherein the leveling structure and the optical structure are spaced apart.

According to an aspect of the disclosure, there is provided a semiconductor package, including: a lower structure; a processor chip, a memory chip, and an optical chip on the lower structure; and a leveling structure and an optical structure on the optical chip, wherein the lower structure includes an integrated circuit structure connecting the processor chip to the optical chip, wherein a level of a top surface of the leveling structure is equal to a level of a top surface of the optical structure, wherein the leveling structure and the optical structure are spaced apart, and a first side surface of the optical structure that faces the leveling structure is exposed.

According to an aspect of the disclosure, there is provided a semiconductor package, including: a lower structure including a first surface and a second surface; a solder pad on the second surface of the lower structure; a solder ball on the solder pad; a processor chip, a memory chip, and an optical chip on the first surface of the lower structure; and a leveling structure and an optical structure on the optical chip, wherein the lower structure includes: an integrated circuit structure connecting the processor chip to the optical chip; and a bridge structure spaced apart from the integrated circuit structure and provided to connect the memory chip to the processor chip, wherein a level of a top surface of the leveling structure is equal to a level of a top surface of the memory chip and a level of a top surface of the processor chip, wherein the leveling structure is spaced apart from the optical structure, and wherein the leveling structure includes silicon.

### BRIEF DESCRIPTION OF DRAWINGS

FIGS. 1 and 2 are sectional views illustrating a semiconductor package according to an embodiment of the disclosure.

FIG. 3 is a sectional view illustrating a semiconductor package according to an embodiment of the disclosure.

FIGS. 4A to 4H are sectional views illustrating a method of fabricating a semiconductor package, according to an embodiment of the disclosure.

### DETAILED DESCRIPTION

Example embodiments of the disclosure will now be described more fully with reference to the accompanying drawings, in which example embodiments are shown.

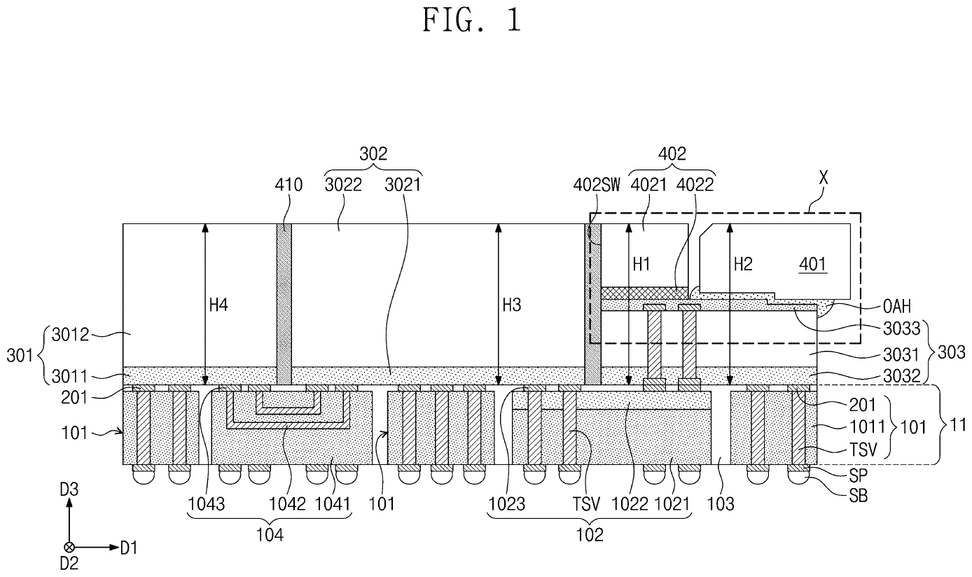

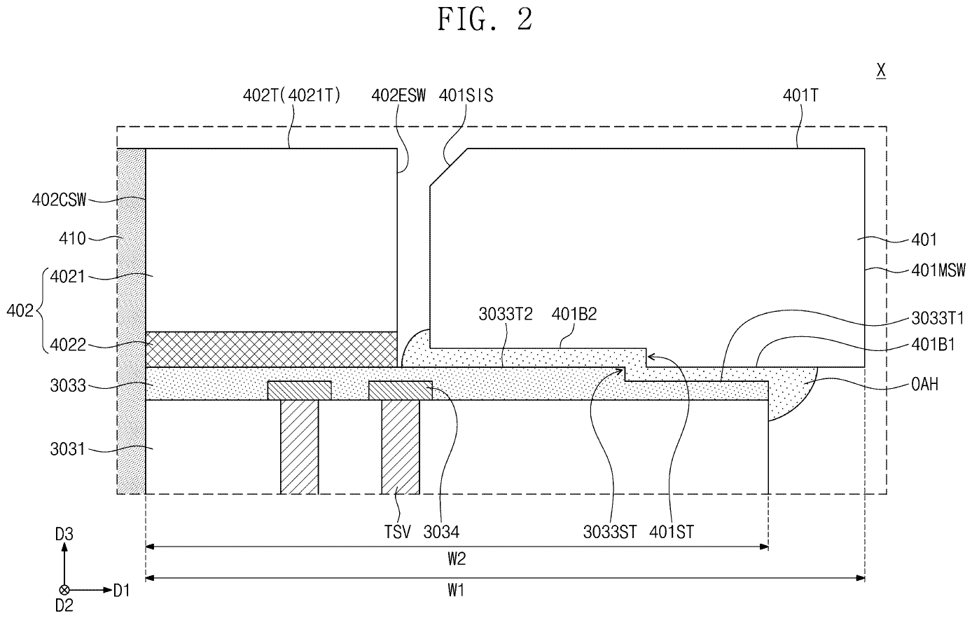

FIGS. 1 and 2 are sectional views illustrating a semiconductor package according to an embodiment of the disclosure.

Referring to FIGS. 1 and 2, a lower structure 11 may be provided. The lower structure 11 may be a plate-shaped structure extended in a first direction D1 and a second direction D2. The first and second directions D1 and D2 may be non-parallel to each other. As an example, the first and second directions D1 and D2 may be horizontal directions that are orthogonal to each other.

According to an embodiment, a memory chip 301, a processor chip 302, and an optical chip 303 may be provided on the lower structure 11. For example, the memory chip 301, the processor chip 302, and the optical chip 303 may be provided on a first surface of the lower structure 11. The first surface may be referred to as an upper surface of the lower structure 11. For example, the memory chip 301, the processor chip 302, and the optical chip 303 may be provided above the lower structure 11. However, the disclosure is not limited thereto, and as such, other components may be provided on the lower structure 11. According to an embodiment, a mold layer 410 may be provided on the memory chip 301 and the processor chip 302. The mold layer 410 may be provided to enclose the memory chip 301 and the processor chip 302. The mold layer 410 may be provided between the processor chip 302 and the optical chip 303. For example, the mold layer 410 may be interposed between the processor chip 302 and the optical chip 303. The mold layer 410 may be referred to as an encapsulation layer. An optical structure 401 and a leveling structure 402 may be provided on the optical chip 303.

The lower structure 11 may overlap the memory chip 301, the processor chip 302, and the optical chip 303 in a third direction D3. The third direction D3 may be perpendicular to the first and second directions D1 and D2. The lower structure 11 may overlap the memory chip 301, the processor chip 302, and the optical chip 303 in a vertical direction.

According to an embodiment, a solder pad SP may be provided on a second surface of the lower structure 11. For example, the solder pad SP may be provided below the lower structure 11. A solder ball SB may be provided on the solder pad SP. The solder ball SB may be connected to the solder pad SP.

The solder pads SP may include a conductive material. As an example, the solder pads SP may be formed of or include copper (Cu). However, the disclosure is not limited thereto, and as such, the solder pads SP may be formed of another material.

The solder balls SB may be provided on the solder pads SP. The semiconductor package may be electrically connected to an external device through the solder balls SB. The solder balls SB may include a conductive material. The solder balls SB may include a solder material. The solder materials may include, but is not limited to, tin, bismuth, lead, silver, or alloys thereof.

The lower structure 11 may include an integrated circuit structure 102 connecting the processor chip 302 to the optical chip 303, a bridge structure 104 connecting the processor chip 302 to the memory chip 301, and a plurality of connection structures 101. The processor chip 302, the optical chip 303, and the memory chip 301 may be connected to corresponding ones of the connection structures 101 and may be connected to the solder balls SB through the corresponding ones of the connection structures 101.

The integrated circuit structure 102 may be spaced apart from the bridge structure 104. The integrated circuit structure 102 may be spaced apart from the connection structure 101. The bridge structure 104 may be spaced apart from the connection structure 101.

The integrated circuit structure 102 may include an integrated circuit chip 1021, an integrated circuit active surface 1022, a plurality of vias TSV, and a plurality of circuit chip pads 1023 on the vias TSV. The penetration vias TSV and the circuit chip pads 1023 may include a conductive material. The plurality of vias TSV may be through-silicon vias (TSV) that penetrate the integrated circuit chip 1021 and the integrated circuit active surface 1022.

The vias TSV of the integrated circuit structure 102 may be connected to the solder pad SP below the integrated circuit structure 102. The vias TSV of the integrated circuit structure 102 may overlap the processor chip 302 in the third direction D3. The vias TSV of the integrated circuit structure 102 may be connected to the processor chip 302. The vias TSV of the integrated circuit structure 102 may not overlap the optical chip 303 in the third direction D3.

An integrated device may be formed on the integrated circuit active surface 1022 of the integrated circuit structure 102. A conductive pad may be formed on the integrated circuit active surface 1022. The integrated circuit chip 1021 of the integrated circuit structure 102 may include an insulating material and a semiconductor material.

The integrated circuit structure 102 may overlap the optical chip 303 and the processor chip 302 in the third direction D3. The integrated circuit chip 1021 may have a size ranging from 150 μm to 300 μm.

The solder pad SP provided below the integrated circuit structure 102 may be electrically connected to the processor chip 302 through the vias TSV and the circuit chip pads 1023.

The solder pad SP below the integrated circuit structure 102 may be electrically connected to the optical chip 303 through the integrated circuit active surface 1022 of the integrated circuit structure 102 and the circuit chip pads 1023 on the integrated circuit active surface 1022.

In an embodiment, a plurality of connection structures 101 may be provided. Each of the optical chip 303, the memory chip 301, and the processor chip 302 may overlap a corresponding one of the connection structures 101 in the third direction D3. Each of the optical chip 303, the memory chip 301, and the processor chip 302 may be connected to a corresponding one of the connection structures 101. For example, the optical chip 303 may overlap a first connection structure 101, the memory chip 301 may overlap a second connection structure 101, and the processor chip 302 may overlap a third connection structure 101. For example, the optical chip 303 may be connected the first connection structure 101, the memory chip 301 may connected to the second connection structure 101, and the processor chip 302 may be connected to the third connection structure 101.

The connection structure 101 may include an insulating chip 1011, which is provided on a solder pad SP, a via TSV, which is connected to the solder pad SP, and a connection pad 201 electrically connected to the via TSV. The via TSV may be provided to penetrate the insulating chip 1011.

One of the connection structures 101 may be connected to one of the optical chip 303, the memory chip 301, and the processor chip 302 and may overlap the one in the third direction D3.

In an embodiment, the optical chip 303, the memory chip 301, and the processor chip 302, which are spaced apart from each other, may be provided on the lower structure 11, and the lower structure 11 may include the connection structures 101, one of which is connected to the optical chip 303, another is overlapped with the memory chip 301, and another is connected to the processor chip 302.

The bridge structure 104 may be provided to be spaced apart from the integrated circuit structure 102. The bridge structure 104 may connect the memory chip 301 to the processor chip 302. The bridge structure 104 may be connected to corresponding ones of the solder pads SP and corresponding ones of the solder balls SB.

The bridge structure 104 may include a bridge chip 1041, a bridge pad 1043, which is provided on the bridge chip 1041, and a bridge interconnection line 1042, which is connected to the bridge pad 1043 and is provided in the bridge chip 1041.

The bridge structure 104 may include a plurality of bridge pads 1043. The bridge pads 1043 may be in contact with the memory chip 301 and the processor chip 302.

The bridge interconnection line 1042 may include the bridge interconnection line 1042, which is provided to connect the bridge pads 1043 in contact with the memory and processor chips 301 and 302. The bridge pad 1043 and the bridge interconnection line 1042 may include a conductive material. The memory chip 301 and the processor chip 302 may be electrically connected to each other through the bridge interconnection line 1042. For example, the bridge interconnection line 1042 may include a first bridge interconnection line 1042 configured to connect a first bridge pad 1043, which is in contact with the memory chip 301, with a second bridge pad 1043, which is in contact with the processor chip 302. Further, the bridge interconnection line 1042 may include a second bridge interconnection line 1042 configured to connect a third bridge pad 1043, which is in contact with the memory chip 301, with a fourth bridge pad 1043, which is in contact with the processor chip 302. Accordingly, the bridge interconnection line 1042 may include a plurality of the bridge interconnection lines.

A lower mold layer 103 may be provided to fill a space between the bridge structure 104, the connection structure 101, and the integrated circuit structure 102. The lower mold layer 103 may include an insulating material. The lower mold layer 103 may be referred to as a lower encapsulation layer.

The memory chip 301 may be provided on the lower structure 11. The memory chip 301 may include, but is not limited to, DRAM, SRAM, MRAM, or FLASH memory chip. The memory chip 301 may include a front portion 3011, which has an active surface, and a rear portion 3012, which is formed of or includes at least one of insulating and semiconductor materials. According to an embodiment, pads may be formed in the front portion 3011 of the memory chip 301. According to an embodiment of the disclosure, the rear portion may be defined as a portion that is opposite to the front portion.

The front portion 3011 of the memory chip 301 may be bonded to the connection pads 201. The pads, which are formed in the front portion 3011 of the memory chip 301, may be connected to the connection pads 201 of the connection structure 101. The front portion 3011 of the memory chip 301 may be connected to the bridge pads 1043.

The processor chip 302 may be provided on the lower structure 11. The processor chip 302 may include a central processing unit (CPU) or a graphics processing unit (GPU), but the disclosure is not limited to this example.

The processor chip 302 may include a front portion 3021, which has an active surface, and a rear portion 3022, which is formed of or includes at least one of insulating and semiconductor materials. The front portion 3021, which includes the active surface of the processor chip 302, may include pads.

The front portion 3021 of the processor chip 302 may be bonded to the connection pads 201. The front portion 3021 of the processor chip 302 may be connected to the bridge pads 1043. The front portion 3021 of the processor chip 302 may be connected to the circuit chip pad 1023.

The optical chip 303 may be provided on the lower structure 11. The optical chip 303 may be provided on the integrated circuit structure 102 and the connection structure 101. The optical chip 303 may include an active surface 3032, a chip portion 3031 on the active surface 3032, and an optical circuit layer 3033 on the chip portion 3031. The active surface 3032 may include including pads. The chip portion 3031 may be formed of or include an insulating material and a semiconductor material. The optical circuit layer 3033 may include circuits and/or pads.

The active surface 3032 of the optical chip 303 may be provided to face the integrated circuit active surface 1022 of the integrated circuit structure 102. Pads in the active surface 3032 of the optical chip 303 may be connected to the circuit chip pads 1023. A via may be provided to penetrate the active surface 3032, the chip portion 3031, and the optical circuit layer 3033 of the optical chip 303. The active surface 3032 and the optical circuit layer 3033 may be electrically connected to each other through the via.

The optical circuit layer 3033 may include a circuit staircase portion 3033ST. The circuit staircase portion 3033ST of the optical circuit layer 3033 may be defined as a portion having a stepwise structure. Since the optical circuit layer 3033 has the circuit staircase portion 3033ST, the optical circuit layer 3033 may have side surfaces, which are located at different heights from each other. A top surface of the optical circuit layer 3033 may be discontinuous before and after the circuit staircase portion 3033ST.

The top surface of the optical circuit layer 3033 may include a first top surface 3033T1, which vertically overlaps the optical structure 401, and a second top surface 3033T2, which is in contact with the leveling structure 402. The first top surface 3033T1 and the second top surface 3033T2 may be discontinuous or may be placed at different levels. A level of the second top surface 3033T2 may be higher than a level of the first top surface 3033T1. According to an embodiment of the disclosure, the level may have the same meaning as a vertical distance or a height that is measured from a bottom surface of the lower structure 11 in the third direction D3. For example, in an example case in which the level of the second top surface 3033T2 is higher than the level of the first top surface 3033T1, a distance from the bottom surface of the lower structure 11 to the second top surface 3033T2 in the third direction D3 may be larger than a distance from the bottom surface of the lower structure 11 to the first top surface 3033T1 in the third direction D3.

The leveling structure 402 and the optical structure 401 may be provided on the optical chip 303.

The leveling structure 402 may be provided on the optical circuit layer 3033 of the optical chip 303. The leveling structure 402 may be provided on the second top surface 3033T2 of the optical circuit layer 3033. The leveling structure 402 may include a leveler 4021 and an adhesive layer 4022. The adhesive layer 4022 may be provided between the leveler 4021 and the second top surface 3033T2 of the optical circuit layer 3033. The adhesive layer 4022 may be an adhesive tape or an adhesive agent.

The leveling structure 402 may include silicon. The leveler 4021 of the leveling structure 402 may include silicon. However, the disclosure is not limited thereto, and as such, the leveler 4021 may be include another material. The leveling structure may be a dummy structure.

The leveling structure 402 may include a contact side surface 402CSW that is in contact with the mold layer 410. A side surface of the leveling structure 402 facing the processor chip 302 may be in contact with the mold layer 410.

The leveling structure 402 may further include an exposed side surface 402ESW that faces the optical structure 401. The exposed side surface 402ESW of the leveling structure 402 may not be in contact with the mold layer 410 and may not be veiled by the mold layer 410.

The optical structure 401 may be provided on the optical circuit layer 3033 of the optical chip 303. The optical structure 401 may be spaced apart from the leveling structure 402. The optical structure 401 may be provided to overlap with the first and second top surfaces 3033T1 and 3033T2 of the optical circuit layer 3033.

The optical structure 401 may be attached to the optical chip 303 by an optical adhesive agent OAH. The optical adhesive agent OAH may be formed at least one of acrylic or epoxy materials.

The optical structure 401 may include a staircase layer 401ST that is offset from the circuit staircase portion 3033ST of the optical circuit layer 3033. Here, the expression “one element is offset from another element” may mean that the elements are spaced apart from each other while maintaining a constant distance between them. For example, the staircase layer 401ST of the optical structure 401 have a shape that conforms to a shape of the circuit staircase portion 3033ST of the optical circuit layer 3033 and/or a size that conforms to a size of the circuit staircase portion 3033ST of the optical circuit layer 3033.

The staircase layer 401ST of the optical structure 401 may include a stepwise portion. Since the optical structure 401 includes the staircase layer 401ST, a bottom surface of the optical structure 401 may be discontinuous. The bottom surface of the optical structure 401 may include a first bottom surface 401B1 and a second bottom surface 401B2, which is closer to the leveling structure 402 than the first bottom surface 401B1. A level of the first bottom surface 401B1 of the optical structure 401 may be lower than a level of the second bottom surface 401B2 of the optical structure 401. The optical structure 401 may include at least one of transparent and refractive materials.

A level of the topmost surface 401T of the optical structure 401 may be equal to a level of the topmost surface 402T of the leveling structure 402. The topmost surface 402T of the leveling structure 402 may be the same as the topmost surface 4021T of the leveler 4021. The optical structure 401 may include an inclined surface 401SIS, which is placed between the topmost surface 401T of the optical structure 401 and a side surface of the optical structure 401 adjacent to the leveling structure 402. Due to the inclined surface 401SIS, a distance between the topmost surface of the optical structure 401 and the leveling structure 402 may be larger than a distance between the bottommost surface of the optical structure 401 and the leveling structure 402. The outermost side surface 401MSW of the optical structure 401 may be defined as a side surface of the optical structure 401 that is opposite to the leveling structure 402.

A distance W1 from a side surface of the optical chip 303 in contact with the mold layer 410 to the outermost side surface 401MSW of the optical structure 401 may be larger than a width W2 of the optical chip 303. The optical structure 401 may protrude, in the first direction D1, relative to the optical chip 303.

The mold layer 410 may be interposed between the memory chip 301 and the processor chip 302, between the processor chip 302 and the optical chip 303, and between the processor chip 302 and the leveling structure 402.

In an embodiment, the semiconductor package may have a flat top surface, due to the presence of the leveling structure 402. A height H4 of the memory chip 301, a height H3 of the processor chip 302, a distance H1 from a bottom surface of the optical chip 303 to a top surface of the leveling structure 402, and a distance H2 from the bottom surface of the optical chip 303 to a top surface of the optical structure 401 may be substantially the same as each other, due to the leveling structure 402. According to embodiments of the disclosure, the term “substantially the same” or “substantially equal to” may mean being within a margin of error of approximately 5%.

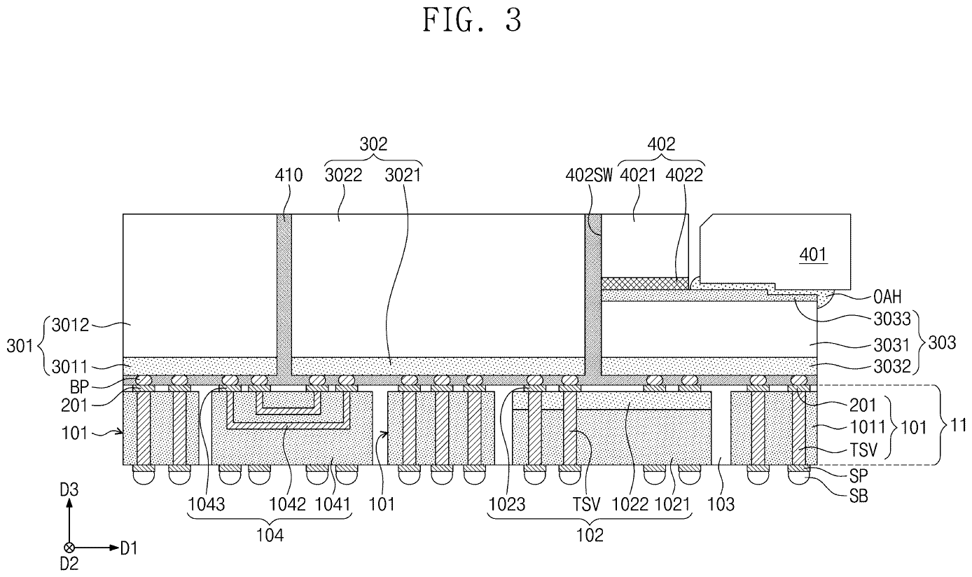

FIG. 3 is a sectional view illustrating a semiconductor package according to an embodiment of the disclosure. For concise description, a previously described element may be identified by the same reference number without repeating an overlapping description thereof.

Referring to FIG. 3, bumps BP may be provided on the connection pad 201, the bridge pad 1043, and the circuit chip pad 1023. The bumps BP may be respectively interposed between the integrated circuit structure 102 and the optical chip 303 and between the integrated circuit structure 102 and the processor chip 302. The bump BP may be interposed between the bridge structure 104 and the processor chip 302. The bump BP may be interposed between the bridge structure 104 and the memory chip 301.

The mold layer 410 may be provided to enclose the bump BP. The bump BP may include a conductive material. The bump BP may be formed of or include, for example, copper.

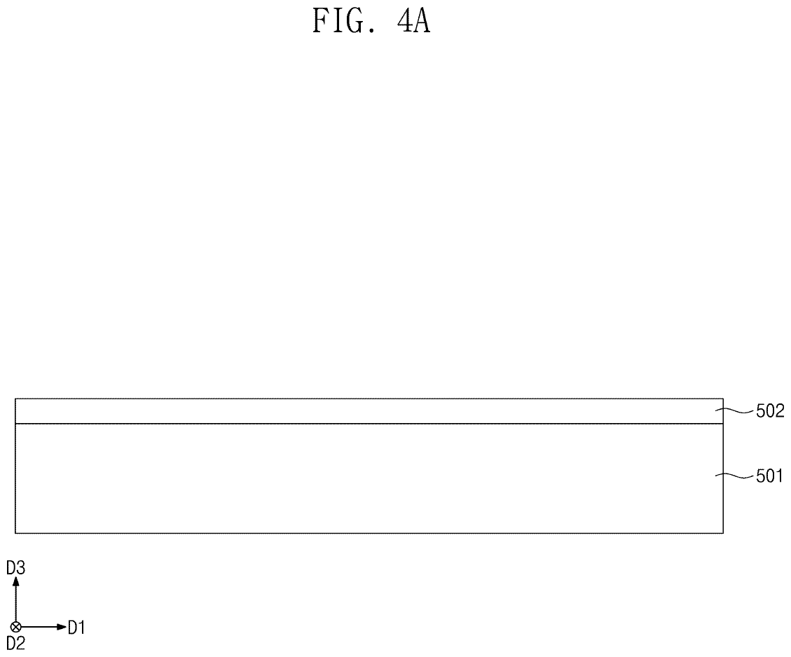

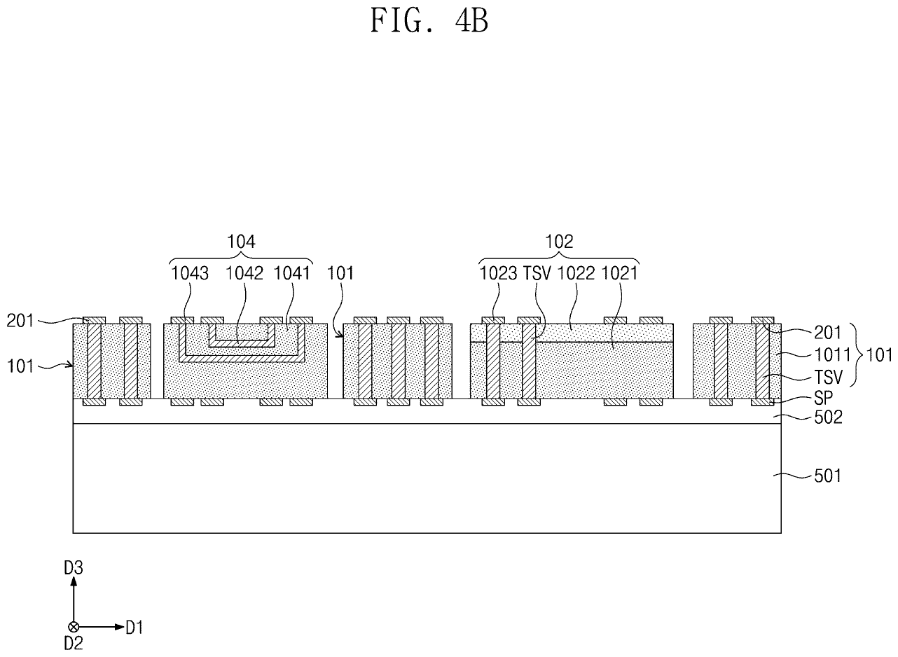

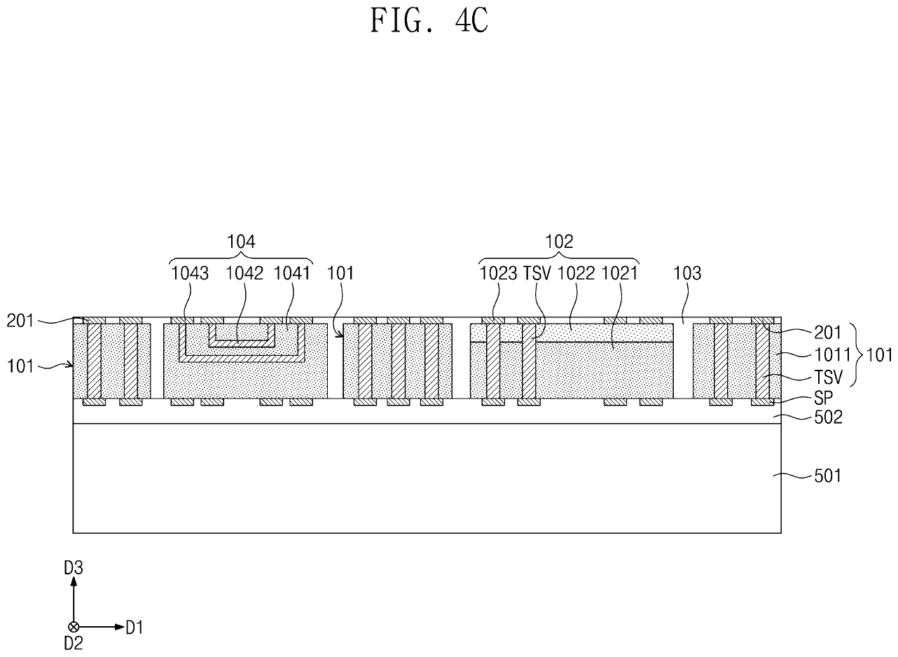

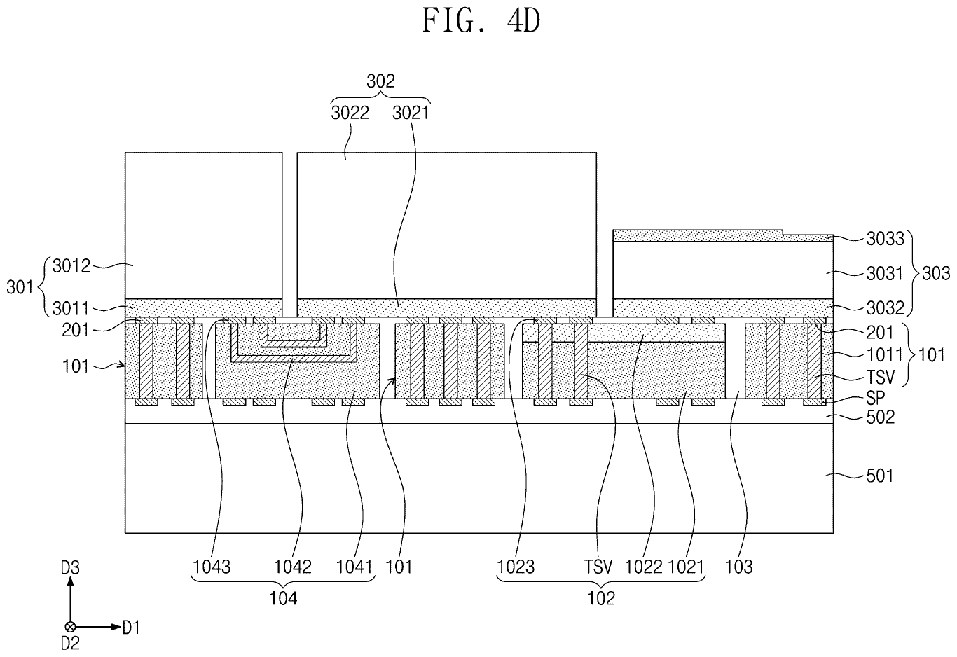

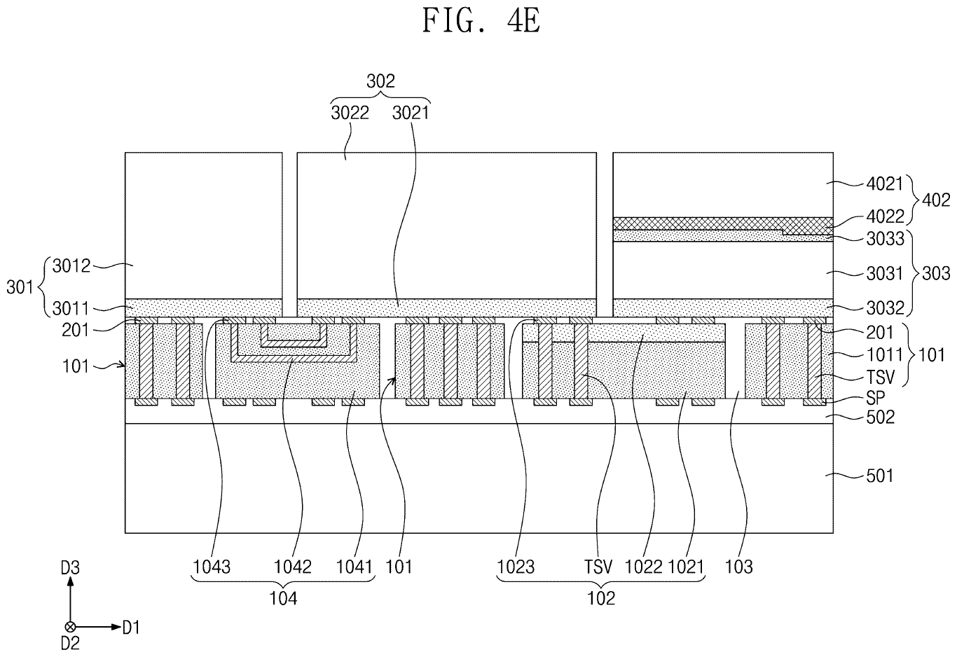

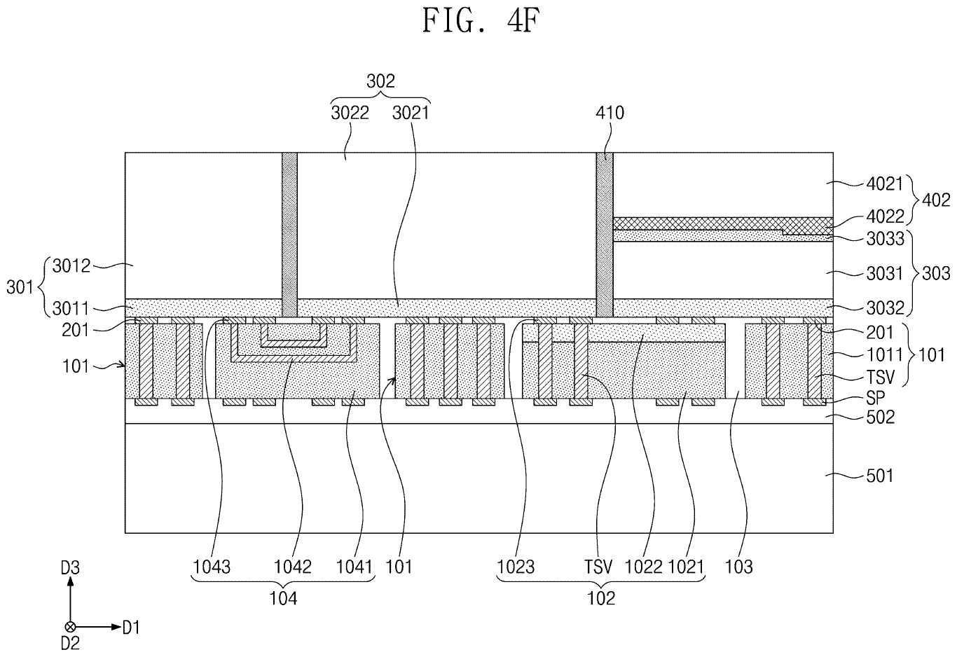

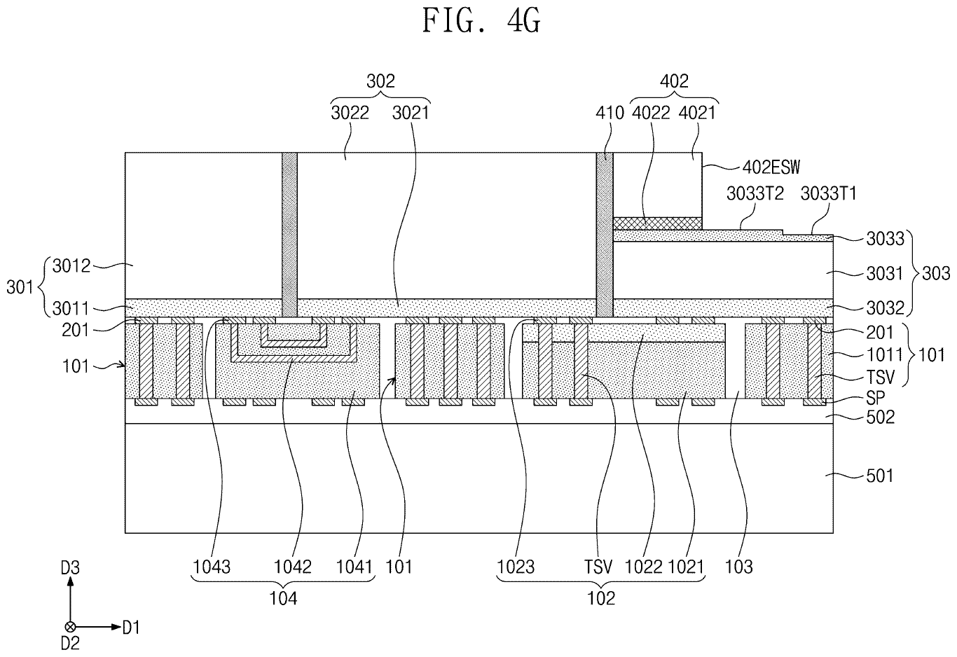

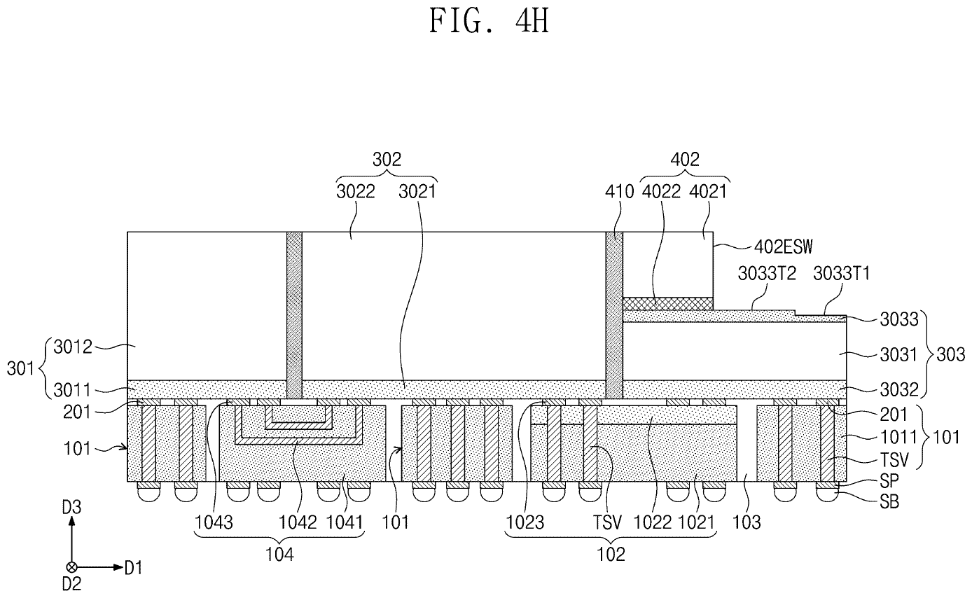

FIGS. 4A to 4H are sectional views illustrating a method of fabricating a semiconductor package, according to an embodiment of the disclosure.

Referring to FIG. 4A, a tape carrier 502 may be provided on a carrier substrate 501. The tape carrier 502 may include an adhesive tape. The tape carrier 502 may include an alignment pin or an alignment key. The carrier substrate 501 may be an insulating substrate a conductive substrate. The insulating substrate may include, but is not limited to, glass or polymer. The conductive substrate may include, but is not limited to, a metallic material.

Referring to FIG. 4B, the solder pads SP, the connection structures 101, the integrated circuit structure 102 and the bridge structure 104 may be placed on and attached to the tape carrier 502. For example, the solder pads SP may be attached to the connection structures 101, the integrated circuit structure 102 and the bridge structure 104, and then, the connection structures 101, the integrated circuit structure 102 and the bridge structure 104 with the solder pads SP may be attached to the tape carrier 502. The connection pads 201 of the connection structures 101, the bridge pads 1043 of the bridge structure 104, and the circuit chip pads 1023 of the integrated circuit structure 102 may be exposed.

Referring to FIG. 4C, the lower mold layer 103 may be formed on the tape carrier 502. For example, the lower mold layer 103 may be formed on the connection structure 101, the bridge structure 104, and the integrated circuit structure 102. For example, the lower mold layer 103 may be formed to enclose the connection structure 101, the bridge structure 104, and the integrated circuit structure 102. The lower mold layer 103 may be formed on the exposed surfaces of the connection pad 201, the bridge pad 1043, and the circuit chip pad 1023. For example, the lower mold layer 103 may be formed to enclose the exposed surfaces of the connection pad 201, the bridge pad 1043, and the circuit chip pad 1023, and then, a planarization process may be performed to expose top surfaces of the connection pad 201, the bridge pad 1043, and the circuit chip pad 1023. The planarization process may include a chemical mechanical planarization (CMP) process. The planarization process may include a grinding process or a chemical-mechanical polishing process.

Referring to FIG. 4D, the memory chip 301, the processor chip 302, and the optical chip 303 may be attached to the connection pad 201, the bridge pad 1043, the circuit chip pad 1023, and the lower mold layer 103 planarized. The attachment of the memory chip 301 may be performed in such a way that the front portion 3011 serving as an active surface is placed at a lower level. The attachment of the memory chip 301 may be performed to bring the front portion 3011 into contact with corresponding ones of the connection pads 201 and corresponding ones of the bridge pads 1043.

The attachment of the processor chip 302 may be performed in such a way that the front portion 3021 serving as an active surface is placed at a lower level. The attachment of the processor chip 302 may be performed to bring the front portion 3021 into contact with corresponding ones of the connection pads 201, corresponding ones of the bridge pads 1043, and corresponding ones of the circuit chip pads 1023.

The attachment of the optical chip 303 may be performed to bring the active surface 3032 into contact with corresponding ones of the connection pads 201 and corresponding ones of the circuit chip pads 1023.

Referring to FIG. 4E, the leveling structure 402 may be attached to the optical chip 303. The attachment of the leveling structure 402 may include providing the adhesive layer 4022 the optical circuit layer 3033 of the optical chip 303 and attaching the leveler 4021 to the adhesive layer 4022. For example, the adhesive layer 4022 may be provided to fully cover the optical circuit layer 3033 of the optical chip 303 and the leveler 4021 may be attached to the adhesive layer 4022. The leveling structure 402 may be attached to cover the entire top surface of the optical chip 303. For example, the leveling structure 402 at this stage of the process may be attached to have a width larger than that of the leveling structure 402 in the final structure of the semiconductor package.

Referring to FIG. 4F, the mold layer 410 may be formed. The mold layer 410 may be formed to fill a space between the memory chip 301, the processor chip 302, the optical chip 303, and the leveling structure 402, which are spaced apart from each other. The formation of the mold layer 410 may include forming the mold layer 410 to cover the memory chip 301, the processor chip 302, and a top surface of the leveling structure 402 and performing a grinding process to expose the memory chip 301, the processor chip 302, and the top surface of the leveling structure 402.

Referring to FIG. 4G, a portion of the leveling structure 402 may be removed. The adhesive layer 4022 and the leveler 4021 of the leveling structure 402 may be removed. As a result, the top surface of the optical circuit layer 3033 may be partially exposed to the outside. The first top surface 3033T1 of the optical circuit layer 3033 may be fully exposed, and the second top surface 3033T2 may be partially exposed. Thereafter, the leveling structure 402 may be removed from a region, to which the optical structure 401 will be attached. Since the leveling structure 402 is removed, the exposed side surface 402ESW of the leveling structure 402, which is not in contact with the mold layer 410, may be exposed.

Referring to FIG. 4H, the carrier substrate 501 and the tape carrier 502 may be removed. Next, the solder ball SB may be formed on the exposed solder pad SP.

Referring back to FIGS. 1 and 2, the optical adhesive agent OAH may be provided on the exposed top surface of the optical circuit layer 3033. The optical structure 401 may be attached to the optical adhesive agent OAH. The optical structure 401 may be attached to be spaced apart from the leveling structure 402. As a result, the semiconductor package of FIGS. 1 and 2 may be fabricated.

In a method of fabricating a semiconductor package according to an embodiment of the disclosure, semiconductor chips may be connected to connection structures formed by dividing a lower substrate. By using the divided connection structures, it may be possible to lower a process difficulty in the fabrication process. Thus, it may be possible to simplify the fabrication process.

In a semiconductor package according to an embodiment of the disclosure, since chips are directly placed on and connected to the connection structures, a length of an electrical signal path may be reduced. The semiconductor package may be provided to have improved electrical characteristics.

While example embodiments of the disclosure have been particularly shown and described, it will be understood by one of ordinary skill in the art that variations in form and detail may be made therein without departing from the spirit and scope of the attached claims.

What is claimed is:

1. A semiconductor package, comprising:
a lower structure;
a processor chip, a memory chip, and an optical chip on the lower structure; and
a leveling structure and an optical structure on the optical chip,
wherein the lower structure comprises:
an integrated circuit structure configured to connect the processor chip to the optical chip, and
a bridge structure spaced apart from the integrated circuit structure, the bridge structure configured to connect the memory chip to the processor chip,
wherein a level of a top surface of the leveling structure is equal to a level of a top surface of the memory chip, and
wherein the leveling structure and the optical structure are spaced apart.

2. The semiconductor package of claim 1, wherein the optical chip and the optical structure are attached using an optical adhesive agent, and
wherein the optical adhesive agent comprises at least one of acrylic or epoxy materials.

3. The semiconductor package of claim 1, wherein the integrated circuit structure comprises a penetration via, and
wherein the penetration via is connected to the processor chip.

4. The semiconductor package of claim 1, further comprising:
a plurality of bumps provided between the integrated circuit structure and the optical chip and between the integrated circuit structure and the processor chip.

5. The semiconductor package of claim 1, wherein the leveling structure comprises silicon.

6. The semiconductor package of claim 1, wherein the optical chip comprises an optical circuit layer in contact with the leveling structure,
wherein the optical circuit layer comprises a circuit staircase portion, and
wherein the optical structure comprises a staircase layer configured to offset the circuit staircase portion.

7. The semiconductor package of claim 1, further comprising:
a mold layer provided between the memory chip and the processor chip and between the leveling structure and the processor chip,
wherein a side surface of the leveling structure that faces the optical structure is exposed.

8. The semiconductor package of claim 7, wherein a distance from a side surface of the optical chip, which is in contact with the mold layer, to an outermost side surface of the optical structure is larger than a width of the optical chip.

9. The semiconductor package of claim 1, wherein the bridge structure comprises:
a plurality of bridge pads in contact with the processor chip and the memory chip; and
a bridge interconnection line connecting a first bridge pad, among the plurality of bridge pads, in contact with the processor chip to a second bridge pad, among the plurality of bridge pads, in contact with the memory chip.

10. A semiconductor package, comprising:
a lower structure;
a processor chip, a memory chip, and an optical chip on the lower structure; and
a leveling structure and an optical structure on the optical chip,
wherein the lower structure comprises an integrated circuit structure connecting the processor chip to the optical chip,
wherein a level of a top surface of the leveling structure is equal to a level of a top surface of the optical structure,
wherein the leveling structure and the optical structure are spaced apart, and
wherein a first side surface of the optical structure that faces the leveling structure is exposed.

11. The semiconductor package of claim 10, wherein the lower structure comprises a bridge structure spaced apart from the integrated circuit structure, and
wherein the bridge structure connects the memory chip and the processor chip.

12. The semiconductor package of claim 11, wherein the lower structure comprises a plurality of connection structures spaced apart from the bridge structure,
wherein the plurality of connection structures are spaced apart from the integrated circuit structure, and
wherein each of the optical chip and the processor chip is connected to a corresponding one of the plurality of connection structures.

13. The semiconductor package of claim 10, wherein the leveling structure comprises silicon.

14. The semiconductor package of claim 10, wherein a first side surface of the leveling structure facing the optical structure is exposed, and
wherein a second side surface of the leveling structure is in contact with a mold layer.

15. The semiconductor package of claim 14, wherein a distance from a second side surface of the optical chip, which is in contact with the mold layer, to an outermost side surface of the optical structure is larger than a width of the optical chip.

16. The semiconductor package of claim 10, wherein the optical chip comprises an optical circuit layer in contact with the leveling structure,
wherein a top surface of the optical circuit layer comprises a first top surface, which vertically overlaps the optical structure, and a second top surface, which is in contact with the leveling structure, and
wherein the first and second top surfaces are placed at different levels to form discontinuous surfaces.

17. The semiconductor package of claim 10, further comprising:
a plurality of bumps provided between the integrated circuit structure and the optical chip and between the integrated circuit structure and the processor chip.

18. The semiconductor package of claim 10, wherein the integrated circuit structure comprises a penetration via,
wherein the penetration via is connected to the processor chip, and
wherein the penetration via does not overlap the optical chip.

19. A semiconductor package, comprising:
a lower structure comprising a first surface and a second surface;
a solder pad on the second surface of the lower structure;
a solder ball on the solder pad;
a processor chip, a memory chip, and an optical chip on the first surface of the lower structure; and
a leveling structure and an optical structure on the optical chip,
wherein the lower structure comprises:
an integrated circuit structure connecting the processor chip to the optical chip; and
a bridge structure spaced apart from the integrated circuit structure and provided to connect the memory chip to the processor chip,
wherein a level of a top surface of the leveling structure is equal to a level of a top surface of the memory chip and a level of a top surface of the processor chip,
wherein the leveling structure is spaced apart from the optical structure, and
wherein the leveling structure comprises silicon.

20. The semiconductor package of claim 19, wherein the optical structure and the optical chip are attached to each other using an optical adhesive agent, and
wherein the optical adhesive agent comprises at least one of acrylic or epoxy materials.
